(19) United States
(12) Patent Application Publication
(10) Pub. No.: US 2025/0354256 A1
(43) Pub. Date: Nov. 20, 2025

(54) SUBSTRATE COMPRISING CONFORMAL METAL CARBIDE COATING

(71) Applicant: SGL CARBON SE, Wiesbaden (DE)

(72) Inventors: Charles WIJAYAWARDHANA, Meitingen (DE); Christian THIELEMANN, Meitingen (DE); Jing-Jia HUANG, Meitingen (DE); Urban FORSBERG, Sturefors (SE); Henrik PEDERSEN, Stigtomta (SE)

(73) Assignee: SGL CARBON SE, Wiesbaden (DE)

(21) Appl. No.: 18/854,157

(22) PCT Filed: Apr. 5, 2023
(86) PCT No.: PCT/EP2023/059028

§ 371 Date: Oct. 4, 2024

(30) Foreign Application Priority Data
Apr. 6, 2022 (DE) 102022203416.3

(51) Int. Cl. C23C 16/32; C23C 16/04

(52) U.S. Cl. CPC C23C 16/325; C23C 16/045

(57) ABSTRACT

A method for coating a substrate with a metal or transition metal carbide by thermal chemical vapor deposition, the method includes placing a substrate in a reaction chamber, and supplying the reaction chamber with SiCl4, ethene and a carrier gas. A process temperature in the reaction chamber is between about 900° C. to about 1050° C.

### TECHNICAL FIELD

The present invention relates to the field of metal carbide coated substrates. More specifically, the present invention relates to graphite substrates coated with a coating of metal carbides characterized by homogenous layer thickness.

### BACKGROUND

Coating substrates with metal carbides may be useful for several applications. For example, metal carbide layers, such as silicon carbide layers, may increase the hardness and/or mechanical strength of the substrate. Further, metal carbide layers may improve the chemical resistance of the coated substrate. Hence, adding metal carbide coatings to substrates may increase their lifetime by increasing for example abrasion and chemical resistance.

Due to their high temperature resistance, specifically the high melting point and thermal conductivity, as well as low coefficient of thermal expansion graphite materials may be used in numerous high-temperature processes. Further, graphite can be used as a susceptor. A susceptor may absorb electromagnetic energy and convert it to heat or re-emit the electromagnetic energy as infrared thermal radiation. Due to its function as a susceptor, relatively high chemical purity and high temperature resistance, graphite may be used in the semi-conductor industry as a wafer carrier, for example for chemical vapor deposition processes.

However, as graphite comprises or substantially consists of carbon it may be prone to chemical attacks. For example, in processes comprising the use of hydrogen, the graphite may be attacked by the hydrogen. Moreover, graphite may still comprise contaminants which may be undesirably transferred to a semi-conductor wafer during high-temperature processes. Further, the surface of graphite may release graphite particles, which can cause damage to the wafer. For example, the surface of graphite may release graphite particles when a wafer disposed therein is moved, e.g. rotated. To increase the chemical resistance, mechanical resistance and to seal contaminants and particles in the graphite, coatings may be added to the graphites surface. In particular, metal carbide coatings, such as silicon carbide coatings, may be used to increase the chemical resistance of the graphite and seals its surface. However, known processes to add metal carbide coatings to substrates exhibit a trade-off. Either, the growth rate of the metal carbide coating is too low to be economically feasible or at least efficient, or the deposited metal carbide coatings cannot penetrate deep enough into recesses, which may lead to the destruction the substrate, as chemical attacks may occur within the recess.

The present disclosure aims to address the aforementioned issues in substrates comprising metal carbide coatings.

### SUMMARY

### Process

In a first aspect, the present disclosure relates to a method for coating a substrate with a metal or transition metal carbide by thermal chemical vapor deposition, wherein the method comprises the following steps:
placing a substrate in a reaction chamber, and
supplying the reaction chamber with SiCl₄, ethene and a carrier gas, and wherein a process temperature in the reaction chamber is between about 900° C. to about 1050° C.

In some embodiments, the process temperature may be between about 925° C. to about 1025° C., more specifically between about 950° C. to about 1000° C.

In some embodiments, the method takes place for a duration between about 20 min to about 600 min, more specifically between about 40 min to about 400 min and in particular between about 60 min to about 240 min.

In some embodiments, the total pressure in the reaction chamber may be between about 1 mbar to about 1085 mbar, more specifically between about 5 mbar to about 100 mbar and in particular between about 7 mbar to about 15 mbar.

In some embodiments, the SiCl₄ and the ethene may be supplied as a precursor mixture, wherein the atomic ratio between silicon and carbon in the precursor mixture may be between about 0.7 to about 1.3, more specifically between about 0.8 to about 1.2, and in particular between about 0.9 to about 1.1.

In some embodiments, the method may comprise a first and second step, wherein the first step comprises supplying the SiCl₄ to the reaction chamber and the second step comprises supplying the ethene to the reaction chamber, in particular wherein the first step and the second step alternate.

In some embodiments, the method may comprise a purge step, wherein the purge step takes place between the first and the second step and/or between the second step and first step, wherein the purge step comprises supplying the reaction with only carrier gas.

In some embodiments, the duration of the first and/or second step may be between about 1 s to about 5 s, more specifically between about 2.5 s to about 3.5 s and/or the duration of the purge step may be between about 0.5 s to about 3 s, more specifically between about 0.8 s to about 1.2 s.

In some embodiments, the carrier gas additionally comprises HCl or Cl₂, and in particular HCl.

In some embodiments, the atomic ratio between chlorine and silicon may be between about 3.5:1 to about 5:1, more specifically between about 3.8:1 to about 4.7:1 and in particular between about 4:1 to about 4.5:1 in the precursor mixture.

In some embodiments, the carrier gas may comprise H₂, more specifically wherein the molar ratio between H₂ and silicon may be between about 10:1 to about 100:1, even more specifically between about 20:1 to about 70:1 and in particular between about 32:1 to about 50:1 in an aggregate of the carrier gas and the precursor mixture.

In some embodiments, the carrier gas additionally may comprise an inert gas, more specifically N₂ and/or Ar and in particular N₂.

In a third aspect, the present disclosure relates to a substrate comprising an outer surface and a recess disposed within the outer surface. The recess comprises a wall segment wherein there is an edge disposed between the outer surface and the wall segment. The outer surface and the wall segment comprise a coating. Further, the wall segment comprises a proximal section, wherein the distance between the edge and the proximal section is 500 μm. The outer surface comprises a first portion adjacent to the edge and the wall segment comprises a second portion adjacent to the edge. The distance between the first portion and the edge and the distance between the second portion and the edge corresponds to 110% of the thickness of the coating in the proximal section. Further, the thickness of the coating of the first portion is between about 80% to about 120%, more specifically between about 90% to about 110% and in particular between about 95% to about 105% of the thickness of the coating of the second portion.

In a second aspect, the present disclosure relates to a substrate, wherein the substrate comprises an outer surface and a recess disposed within the outer surface. Further, the recess comprises a wall segment comprising a metal carbide coating, wherein there is an edge disposed between the outer surface and the wall segment. The wall segment comprises a proximal section and a distal section, wherein the proximal section is located closer to the edge compared to the distal section. The distance between the proximal section and the distal section in a direction perpendicular to the outer surface is at least 100 μm. The metal carbide coating in the distal section has at least 70% of the thickness of the metal carbide coating in the proximal section.

### Coating Dimensions

In some embodiments, the thickness of the metal carbide coating in the proximal section may be between about 20 μm to about 300 μm, more specifically between about 50 μm to about 250 μm and in particular between about between about 80 μm to about 150 μm.

In some embodiments, the distance between the proximal section and the distal section may be at least about 200 μm, more specifically at least about 400 μm and in particular at least about 600 μm.

In some embodiments, the distance between the proximal section and the edge may be at least about 200 μm, more specifically at least about 400 μm and in particular at least about 600 μm.

In some embodiments, the distance between the proximal section and edge may be between about 200 μm to about 2 cm, more specifically between about 400 μm to about 1 cm and in particular between about 600 μm to about 800 μm.

In some embodiments, the outer surface also may comprise the metal carbide coating.

In some embodiments, the thickness of the metal carbide coating of the distal section may be between about 80% to about 200%, more specifically between about 90% to about 160% and in particular between about 95% to about 120% of the thickness of the coating of the proximal section.

In some embodiments, the thickness of the metal carbide coating of the distal section may be between about 80% to about 200%, more specifically between about 90% to about 160% and in particular between about 95% to about 120% of the thickness of the metal carbide coating on the outer surface.

In some embodiments, the wall segment may have a length of between about 200 μm to about 50 cm, more specifically between about 5 mm to about 40 cm and in particular between about 5 cm to about 30 cm.

### Orientation of Planes

In some embodiments, the wall segment and the outer surface may be disposed at an angle to one another, more specifically wherein the angle may be between about 45° to about 135°, in particular wherein the angle may be between about 70° to about 110° and even more particularly wherein the angle may be between about 85° to about 95°.

In some embodiments, the wall segment and the outer surface may be disposed substantially orthogonally or orthogonally to one another.

In some embodiments, the wall segment may have an opposing wall segment, wherein the distance between the wall segment and the opposing wall segment may be between about 250 μm to about 25000 μm, more specifically between about 500 μm to about 10000 μm and in particular between about 1000 μm to about 7500 μm.

In some embodiments, a ratio between a length of the wall segment and the distance between the wall segment and the opposing wall segment may be at least 1:1, more specifically at least 5:1, even more specifically at least 10:1 and in particular at least 20:1.

In some embodiments, the ratio between the length of the wall segment and the distance between the wall segment and the opposing wall segment may be between about 1:1 to about 100:1, more specifically between about 10:1 to about 75:1 and in particular between about 20:1 to about 50:1.

### Edges

In some embodiments, the metal carbide coating follows the contour of the underlying substrate, in particular wherein the metal carbide coating follows the contour of the underlying substrate at the edge.

In some embodiments, the variation of thickness of the metal carbide coating along the edge may be less than 60%, more specifically less than 50% and in particular less than 45%.

In some embodiments, the outer surface may comprise a first portion adjacent to the edge and the wall segment may comprise a second portion adjacent to the edge, wherein the distance between the first portion and the edge and the distance between the second portion and the edge corresponds to 110% of the thickness of the metal carbide coating in the proximal section, and wherein the thickness of the metal carbide coating of the first portion may be between about 80% to about 120%, more specifically between about 90% to about 110% and in particular between about 95% to about 105% of the thickness of the metal carbide coating of the second portion.

In some embodiments, the thickness of the metal carbide coating of the first portion may be between about 80% to about 120%, more specifically between about 90% to about 110% and in particular between about 95% to about 105% of the thickness of the metal carbide coating in the proximal section.

In some embodiments, the thickness of the metal carbide coating of the second portion may be between about 80% to about 120%, more specifically between about 90% to about 110% and in particular between about 95% to about 105% of the thickness of the metal carbide coating in the proximal section.

In some embodiments, the edge may be an outer edge.

In some embodiments, the edge may be an inner edge.

### Substrate Material

In some embodiments, the substrate may comprise carbon, more specifically wherein the substrate may comprise at least about 90 wt.-% carbon and in particular wherein the substrate may comprise at least about 99 wt.-% carbon, relative to the total weight of the substrate.

In some embodiments, the substrate may comprise graphite, more specifically wherein the substrate may comprise at least about 90 wt.-% graphite and in particular wherein the substrate may comprise at least about 99 wt.-% graphite, relative to the total weight of the substrate.

In some embodiments, the substrate may comprise silicon, more specifically wherein the substrate may comprise at least about 90 wt.-% silicon and in particular wherein the substrate may comprise at least about 99 wt.-% silicon, relative to the total weight of the substrate.

In some embodiments, the substrate may comprise isostatic graphite, more specifically wherein the substrate may comprise at least about 90 wt.-% isostatic graphite and in particular wherein the substrate may comprise at least about 99 wt.-% isostatic graphite, relative to the total weight of the substrate.

In some embodiments, the substrate may comprise CFRC, more specifically wherein the substrate may comprise at least about 90 wt.-% isostatic graphite and in particular wherein the substrate may comprise at least about 99 wt.-% CFRC, relative to the total weight of the substrate.

In some embodiments, the substrate may be a cylinder, more specifically a cylinder with a diameter between about 5 cm to about 100 cm and in particular a cylinder with a diameter between about 15 cm to about 80 cm.

In some embodiments, the cylinder may have thickness between about 1 mm to about 10 cm, more specifically between about 3 mm to about 5 cm and in particular between about 5 mm to about 3 cm.

In some embodiments, the outer surface may comprise at least one disc-shaped pocket, wherein the diameter of the recess may be between about 45 mm to about 700 mm, more specifically between about 100 mm to about 475 mm and in particular between about 150 mm to about 300 mm and/or wherein the depth of the pocket may be between about 100 μm to about 2000 μm, more specifically between about 250 μm to about 1500 μm and in particular between about 500 μm to about 1000 μm.

### Coating Material

In some embodiments, the coating may comprise metal carbide coating may comprise at least about 90 wt.-% of a metal carbide, more specifically the metal carbide coating may comprise at least about 99 wt.-% of a metal carbide, relative to the total weight of the coating and in particular the metal carbide coating may consist of the metal carbide.

In some embodiments, the metal carbide may comprise silicon carbide.

In some embodiments, the coating may comprise a plurality of carbide crystals.

In some embodiments, the metal carbide coating may be characterized by a full-width-half-maximum of the (111) peak between about 0.300° to about 1.000°, more specifically between about 0.350° to about 0.800° and in particular between about 0.400° to about 0.750°, measured by XRD.

### Gas Channel

In some embodiments, the wall segment may comprise a first wall section and a second wall section, wherein the first and second wall section may be disposed at angle to one another.

In some embodiments, the second wall section extends orthogonally to the first wall section.

In some embodiments, the first wall section may have a length between about 0.1 cm to about 3 cm, more specifically between about 0.5 cm to about 2 cm and in particular between about 1 cm to about 1.5 cm.

In some embodiments, the second wall section may have a length between about 1 cm to about 100 cm, more specifically between about 5 cm to about 75 cm and in particular between about 25 cm to about 50 cm.

In some embodiments, the recess may have a first and a second opening, wherein the first opening may be disposed within the outer surface and the second opening may be disposed on a second outer surface of the substrate.

In some embodiments, a second edge may be disposed between the first and second wall section, and wherein the first wall sections may comprise a third portion adjacent to the second edge and the second wall section may comprise a fourth portion adjacent to the second edge, wherein the distance between the third portion and the second edge and the distance between the fourth portion and the edge corresponds to 110% of the thickness of the coating in the proximal section, and wherein the thickness of the coating of the first portion may be between about 80% to about 120%, more specifically between about 90% to about 110% and in particular between about 95% to about 105% of the thickness of the coating of the second portion.

### DETAILED DESCRIPTION

Hereinafter, a detailed description will be given of the present disclosure. The terms or words used in the description and the aspects of the present disclosure are not to be construed limitedly as only having common-language or dictionary meanings and should, unless specifically defined otherwise in the following description, be interpreted as having their ordinary technical meaning as established in the relevant technical field. The detailed description will refer to specific embodiments to better illustrate the present disclosure, however, it should be understood that the presented disclosure is not limited to these specific embodiments.

Coatings, in particular metal carbide coatings may deposited on substrates by chemical vapor deposition. One variation of chemical vapor deposition is thermal chemical vapor deposition, wherein the reaction energy for the coating deposition/formation is provided by high temperatures. Typically, gaseous precursors are carried into a reaction chamber by a carrier gas. The combination of carrier gas and gaseous precursor may be referred to as main gas flow. The main gas flow may also comprise H₂.

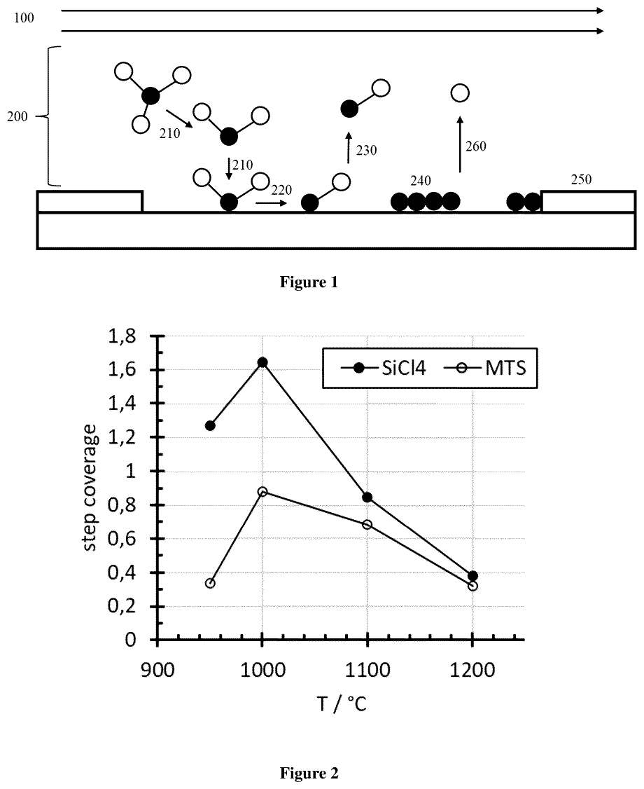

FIG. 1 shows the processes in a thermal chemical vapor deposition process. Precursor molecules and potentially H₂ from the main gas flow may diffuse into a boundary layer disposed between the main gas flow and a substrate's surface. Within the boundary layer the precursor may decompose and/or react with H₂ to form a reactive species and the reactive species may then be transported to the substrates surface. At the substrates surface the reactive species may adsorb to surface. At the surface, the reactive species may further undergo change due to surface reactions. Part of the reactive species, more specifically volatile surface reaction products, may also desorb from the surface, reducing the rate of coating formation.

Multiple reactive species may react to form a nucleus. The nucleus may expand by a step growth process, wherein the nucleus' edges may react with further reactive species.

In general, it is expected that higher temperatures in a chemical vapor deposition process lead to a higher coating growth rate as the rate reactive species formation in the gas phase is increased.

In substrates comprising features which extend from an outer surface into the substrate's bulk, e.g. a recess, the deposited coating is typically thicker on the outer surface than within the recess.

It is believed most chemical vapor deposition processes are limited by a trade-off between coating growth rate and penetration depth. If the reaction rate of the precursor is increased the coating growth rate is increased. However, the higher reaction rate also leads to a higher rate of depletion of the precursor in the gas stream penetrating into the recess. As a result, with increasing coating deposition rate, the penetration depth into the recess and the uniformity of the coating along the recess is reduced.

It has been surprisingly found, that the combination of silicon tetrachloride (SiCl₄) and ethene (C₂H₄) as reaction gases in a thermal chemical vapor deposition process may lead to a process with a high growth rate and high penetration depth and coating uniformity of a silicon carbide coating along a recess, if performed at temperatures between about 900° C. to about 1050° C.

### Process

Accordingly, in a first aspect, the present disclosure relates to a method for coating a substrate with a metal or transition metal carbide by thermal chemical vapor deposition, wherein the method comprises the following steps:
placing a substrate in a reaction chamber, and
supplying the reaction chamber with SiCl₄, ethene and a carrier gas, and wherein a process temperature in the reaction chamber is between about 900° C. to about 1050° C.

The thermal chemical vapor deposition process comprises a multiplicity of chemical reactions and is partly not understood in every detail. However, without wishing to be bound by theory, it is believed that during the surface reaction chlorine reversibly adsorbs to the surface at reaction sites of the substrate. The adsorbed chlorine temporarily blocks the reaction site. The chlorine in the process is a reaction product of the silicon carbide deposition and hence, the rate of chlorine generation is dependent on the deposition rate. As the rate of chlorine generation is dependent on the rate of reactive species adsorbing to the surface, the reaction can be regarded as being self-regulated. The reaction sites may hence form a bottleneck, which may lead to the reaction kinetic of the coating deposition reaction to approach a zero-order reaction, as long as the concentration of the chlorine is above a certain threshold and the temperature is within a certain range. A zero-order reaction is a chemical reaction wherein the rate does not vary with the increase or decrease in the concentration of the reactants, e.g. the precursor.

Without wishing to be bound by theory, diffusion may be the limiting process for the precursor to get into recesses. Diffusion is a time dependent process, as is the coating deposition process. As a result, it is generally expected that the concentration of a precursor from a main gas flow is depleted on the way into a recess. As reaction rates, except for zero-order reactions, are concentration dependent, a lower deposition rate and hence a small coating thickness is commonly expected within the recess than at the outer surface in chemical vapor deposition process. Similarly, a smaller coating thickness is expected at a location in the recess closer to the outer surface compared to one further removed from the outer surface.

When the reaction kinetic becomes close to zero-order, this may increase the penetration depth and in particular the coating thickness homogeneity within a recess. Due to the reactive site blocking, the reactants do not react predominantly at the entrance into the recess as would likely occur in conventional processes with deposition rates. Hence, the penetration depth and in particular the coating thickness homogeneity may be increased.

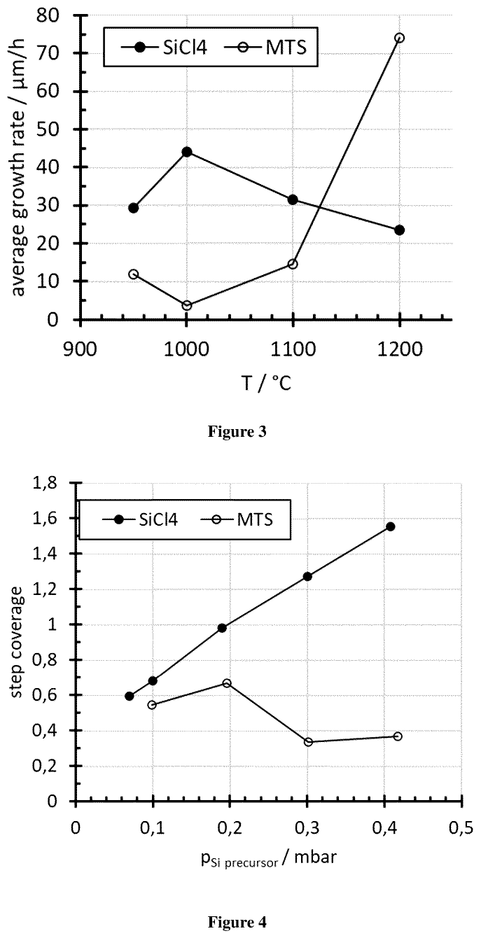

A commonly used precursor for depositing silicone carbide films on substrates is methyltrichlorosilane. Methylchlorosilane, MTS, has a ratio of silicon to chlorine of 1:3, whereas SiCl₄ has a ratio of 1:4. Considering the above mentioned theory, it would be expected that the growth rate of SiCl₄ would be reduced compared to MTS. As can be seen in FIG. 3 the growth rate of SiCl₄ unexpectedly exceeds that of MTS within the temperature range between 900° C. to about 1050° C.

Further, as presented in the FIGS. 2 and 4, the use SiCl₄ leads to an improved step coverage compared to MTS. The step coverage was calculated for a recess, in particular a trench, with a depth of 1000 μm and width of 300 μm, by the following formula:

$$step coverage = \frac{{t}_{b o t t o m}}{{t}_{t o p}}$$

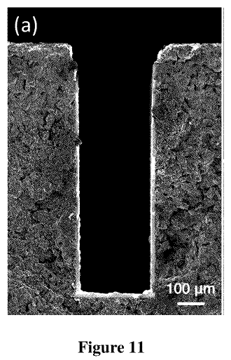

The improved homogeneity of the coating can also be seen in in FIG. 10 and FIG. 11. FIG. 10 shows a coating applied with a conventional process, whereas FIG. 11 shows a coating applied with the method according to the first aspect.

Further results will be discussed in the experimental section.

In some embodiments, the process temperature may be between about 925° C. to about 1025° C., more specifically between about 950° C. to about 1000° C. As can be seen in FIG. 2 and FIG. 3, these temperatures may lead to an optimal step coverage and growth rate.

In some embodiments, the method takes place for a duration between about 20 min to about 600 min, more specifically between about 40 min to about 400 min and in particular between about 60 min to about 240 min.

In some embodiments, the total pressure in the reaction chamber may be between about 1 mbar to about 1085 mbar, more specifically between about 5 mbar to about 100 mbar and in particular between about 7 mbar to about 15 mbar.

In some embodiments, the SiCl₄ and the ethene may be supplied as a precursor mixture, wherein the atomic ratio between silicon and carbon in the precursor mixture may be between about 0.7 to about 1.3, more specifically between about 0.8 to about 1.2, and in particular between about 0.9 to about 1.1. The silicon to carbon ratio may be adjusted for example by adding MTS into the precursor gas mixture to adjust properties of the coating.

In some embodiments, the precursor mixture comprises less than 30 mol.-%, more specifically less than 20 mol.-%, even more specifically less than 10 mol.-% and in particular substantially no or no other carbon source other than ethene, relative to the total precursor mixture. In some embodiments, the precursor mixture comprises less than 30 mol.-%, more specifically less than 20 mol.-%, even more specifically less than 10 mol.-% and in particular substantially no or no other silicon source other than SiCl₄.

In some embodiments, the method may comprise a first and second step, wherein the first step comprises supplying the SiCl₄ to the reaction chamber and the second step comprises supplying the ethene to the reaction chamber, in particular wherein the first step and the second step alternate.

In some embodiments, the method may comprise a purge step, wherein the purge step takes place between the first and the second step and/or between the second step and first step, wherein the purge step comprises supplying the reaction with only carrier gas.

Supplying the SiCl₄ in a first and the ethene in a second step, in particular when supplying only carrier gas in a purge step in between the first and second step, may lead to a metal carbide coating of increased conformity. Without wishing to be bound by theory, the SiCl₄ may diffuse into the recess when and after being supplied in the first step. As diffusion is time and concentration dependent, the concentration of the SiCl₄ is expected to be higher at parts of the recess closer to the edge and/or outer surface when the carrier gas is supplied in the purge step. However, the purge step may remove more SiCl₄ close to the edge and/or outer surface compared to deeper within the recess. Still, without wishing to be bound by theory, this may equalize the concentration of SiCl₄ along the depth of the recess or even lead to a higher concentration of SiCl₄ deeper in the recess compared to closer to the edge/outer surface. Subsequently, when the ethene is suppled the reaction rate may be concentration dependent. As a result, the reaction rate along the depth of the recess may be equalized or may even be higher deeper in the recess compared to close to the edge/outer surface. A following purge step may again equalize the concentration of SiCl₄ and ethene along the depth of the recess, or even lead to a higher concentration within the recess, allowing for a more homogenous reaction rate along the recess or an increased reaction rate deeper within the recess. The first, second and purge step may be repeated. Further, the method may start with the second step.

In some embodiments, the duration of the first and/or second step may be between about 1 s to about 5 s, more specifically between about 2.5 s to about 3.5 s and/or the duration of the purge step may be between about 0.5 s to about 3 s, more specifically between about 0.8 s to about 1.2 s.

In some embodiments, the carrier gas additionally comprises HCl. It has been surprisingly found, that the addition of HCl, may lead to an increased step coverage. However, an increased proportion of may reduce the coating's growth rate. In some embodiments, the carrier gas additionally comprises Cl₂. Cl₂ may also lead to an increased step coverage due to the reactive site blocking.

In some embodiments, the atomic ratio between chlorine and silicon may be between about 3.5:1 to about 5:1, more specifically between about 3.8:1 to about 4.7:1 and in particular between about 4:1 to about 4.5:1 in the precursor mixture. An increased proportion of chlorine, for example by adding HCl, may lead to an increased step coverage. However, an increased proportion of may reduce the coating's growth rate.

In some embodiments, the carrier gas may comprise H₂, more specifically wherein the molar ratio between H₂ and silicon may be between about 10:1 to about 100:1, even more specifically between about 20:1 to about 70:1 and in particular between about 32:1 to about 50:1 in an aggregate of the carrier gas and the precursor mixture.

In some embodiments, the carrier gas additionally may comprise an inert gas, more specifically N₂ and/or Ar and in particular N₂.

### Substrate to be Used in the Coating Method

Hereafter embodiments of the substrates to be used in the coating method of the first aspect are described.

In some embodiments, the substrate (placed into the reaction chamber) may comprise an outer surface and a recess disposed within the outer surface. Further, the recess may comprise a wall segment, wherein there is an edge disposed between the outer surface and the wall segment. The wall segment may comprise a proximal section and a distal section, wherein the proximal section is located closer to the edge compared to the distal section. The distance between the proximal section and the distal section in a direction perpendicular to the outer surface may be at least 100 μm.

In some embodiments, the distance between the proximal section and the distal section may be at least about 200 μm, more specifically at least about 400 μm and in particular at least about 600 μm.

In some embodiments, the distance between the proximal section and the edge may be at least about 200 μm, more specifically at least about 400 μm and in particular at least about 600 μm.

In some embodiments, the distance between the proximal section and edge may be between about 200 μm to about 2 cm, more specifically between about 400 μm to about 1 cm and in particular between about 600 μm to about 800 μm.

In some embodiments, the wall segment may have a length of between about 200 μm to about 50 cm, more specifically between about 5 mm to about 40 cm and in particular between about 5 cm to about 30 cm.

In some embodiments, the wall segment and the outer surface may be disposed at an angle to one another, more specifically wherein the angle may be between about 45° to about 135°, in particular wherein the angle may be between about 70° to about 110° and even more particularly wherein the angle may be between about 85° to about 95°.

In some embodiments, the wall segment and the outer surface may be disposed substantially orthogonally or orthogonally to one another.

In some embodiments, the wall segment may have an opposing wall segment, wherein the distance between the wall segment and the opposing wall segment may be between about 250 μm to about 25000 μm, more specifically between about 500 μm to about 10000 μm and in particular between about 1000 μm to about 7500 μm.

In some embodiments, a ratio between a length of the wall segment and the distance between the wall segment and the opposing wall segment may be at least 1:1, more specifically at least 5:1, even more specifically at least 10:1 and in particular at least 20:1.

In some embodiments, the ratio between the length of the wall segment and the distance between the wall segment and the opposing wall segment may be between about 1:1 to about 100:1, more specifically between about 10:1 to about 75:1 and in particular between about 20:1 to about 50:1.

In some embodiments, the edge may be an outer edge.

In some embodiments, the edge may be an inner edge.

In some embodiments, the substrate may comprise carbon, more specifically wherein the substrate may comprise at least about 90 wt.-% carbon and in particular wherein the substrate may comprise at least about 99 wt.-% carbon, relative to the total weight of the substrate.

In some embodiments, the substrate may comprise graphite, more specifically wherein the substrate may comprise at least about 90 wt.-% graphite and in particular wherein the substrate may comprise at least about 99 wt.-% graphite, relative to the total weight of the substrate.

In some embodiments, the substrate may comprise silicon, more specifically wherein the substrate may comprise at least about 90 wt.-% silicon and in particular wherein the substrate may comprise at least about 99 wt.-% silicon, relative to the total weight of the substrate.

In some embodiments, the substrate may comprise isostatic graphite, more specifically wherein the substrate may comprise at least about 90 wt.-% isostatic graphite and in particular wherein the substrate may comprise at least about 99 wt.-% isostatic graphite, relative to the total weight of the substrate.

In some embodiments, the substrate may comprise CFRC, more specifically wherein the substrate may comprise at least about 90 wt.-% isostatic graphite and in particular wherein the substrate may comprise at least about 99 wt.-% CFRC, relative to the total weight of the substrate.

In some embodiments, the substrate may be a cylinder, more specifically a cylinder with a diameter between about 5 cm to about 100 cm and in particular a cylinder with a diameter between about 15 cm to about 80 cm.

In some embodiments, the cylinder may have thickness between about 1 mm to about 10 cm, more specifically between about 3 mm to about 5 cm and in particular between about 5 mm to about 3 cm.

In some embodiments, the outer surface may comprise at least one disc-shaped pocket, wherein the diameter of the recess may be between about 45 mm to about 700 mm, more specifically between about 100 mm to about 475 mm and in particular between about 150 mm to about 300 mm and/or wherein the depth of the pocket may be between about 100 μm to about 2000 μm, more specifically between about 250 μm to about 1500 μm and in particular between about 500 μm to about 1000 μm.

In some embodiments, the substrate may comprise one or more gas channels.

In some embodiments, the wall segment may comprise a first wall section and a second wall section, wherein the first and second wall section may be disposed at angle to one another.

In some embodiments, the second wall section extends orthogonally to the first wall section.

In some embodiments, the first wall section may have a length between about 0.1 cm to about 3 cm, more specifically between about 0.5 cm to about 2 cm and in particular between about 1 cm to about 1.5 cm.

In some embodiments, the second wall section may have a length between about 1 cm to about 100 cm, more specifically between about 5 cm to about 75 cm and in particular between about 25 cm to about 50 cm.

In some embodiments, the recess may have a first and a second opening, wherein the first opening may be disposed within the outer surface and the second opening may be disposed on a second outer surface of the substrate.

### Coated Substrate

The method according to the first aspect, is able to provide a substrate with an improved coating geometry. In particular, the method according to the first aspect may be used to provide a substrate with a metal carbide coating, wherein the metal carbide coating has a similar thickness within a section of a recess disposed closer to the outer surface, as another section disposed further away from the outer surface.

In a second aspect, the present disclosure relates to a substrate, wherein the substrate comprises an outer surface and a recess disposed within the outer surface. Further, the recess comprises a wall segment comprising a metal carbide coating, wherein there is an edge disposed between the outer surface and the wall segment. The wall segment comprises a proximal section and a distal section, wherein the proximal section is located closer to the edge compared to the distal section. The distance between the proximal section and the distal section in a direction perpendicular to the outer surface is at least 100 μm. The metal carbide coating in the distal section has at least 70% of the thickness of the metal carbide coating in the proximal section.

The thickness in the proximal and/or the distal section may be averaged over a length of 10 μm along the wall segment. For example, if the recess extends into the bulk perpendicular to the surface, the proximal segment may be the average thickness of the metal carbide coating disposed next to the edge. For sections which are disposed at a specific distance from a reference point, such as the distal section, the start and end point for averaging the metal carbide coating thickness may be equidistant from the intended distance from the reference point. For example, the thickness of the metal carbide coating in the distal section may be averaged starting from a point disposed 95 μm away from the proximal section in perpendicular direction to a point disposed 105 μm away from the proximal section in distal direction.

Further, the thickness of the metal carbide coating may be measured in perpendicular direction to the underlying surface.

The term “outer surface” within this disclosure may refer to a surface, wherein in a direction perpendicular to the surface no other surface of the substrate is disposed. Alternatively or additionally, the term “outer surface” within this disclosure may refer to a surface, wherein at least one reference point on the surface is not enclosed by at least 50% by a wall segment extending away from the bulk. Alternatively or additionally, the term “outer surface” may refer to a surface, wherein at least one reference point on the surface is not surrounded by a wall segment with a height of at least 1 cm extending away from the bulk within a radius of at least 2.5 cm, more specifically at least 3.5 cm and in particular at least 4 cm. For example, the substrate may comprise disc-shaped pockets, wherein the radius of the pockets is 700 mm. The interior of the pockets may still be regarded as an outer surface and not as a recess. Known processes may be used to provide metal carbide coatings on flat pockets with high diameters, as these are easily reached by the main gas flow. The method according to the first aspect however, is able provide metal carbide coatings on recesses of high depths and/or with smaller diameters compared to flat pockets.

The term “wall segment” refers to a part of a wall, more specifically to a part of a wall with a length of at least 100 μm and in particular to a part of wall with a length of at least 100 μm and a width of at least 10 μm. The width may also be measured along a curved wall segment, along the curved surface. A rectangular recess, wherein rectangular recess refers to a recess with a rectangular top view, may for example be divided into four wall segments, each wall segment representing one side of the rectangle. A circular wall, e.g. a wall of a recess with a circular top view, such as a bore, may also be divided into multiple wall segments. The term “top view” may refer to a view onto the outer surface, in particular a view onto the outer surface in a direction perpendicular to the outer surface.

The substrate according to the second aspect may be used for example in the semi-conductor industry as a wafer carrier. Such wafer carriers may have recesses in their outer surface for functionality. For example, the wafer carriers may comprise gas channels, wherein the gas channels may be used to transport gases to rotate the wafer and/or the wafer carrier during a wafer coating process. However, wafer coating processes may be performed at elevated temperatures. As a result, if the substrate comprises a material prone to chemical attacks such as graphite, the gas stream may chemically attack the material along the gas channel, e.g. along a wall segment of the recess. A metal carbide coating, in particular a silicon carbide coating, may protect the underlying substrate from chemical attacks. Hence, a coating which penetrates deeper into the recess or coats longer section of the wall segment, with a higher thickness, may improve the chemical resistance of the substrate.

### Coating Dimensions

In some embodiments, the thickness of the metal carbide coating in the proximal section may be between about 20 μm to about 300 μm, more specifically between about 50 μm to about 250 μm and in particular between about between about 80 μm to about 150 μm. Typically, processes able to provide metal carbide coatings into recesses and/or homogenous metal carbide coatings lead to decreased growth rates compared to processes which mainly deposit the metal carbide coating at the outer surface and parts of the recess located in proximity of the outer surface. As a result, processes able to provide metal carbide coatings penetrating into the recess and/or homogenous metal carbide coatings, lead to low metal carbide coating thicknesses, as higher metal carbide coating thicknesses can only be achieved with excessive coating durations. A higher metal carbide coating thickness may improve the chemical resistance. Further, a higher metal carbide coating thickness may more effectively prevent the diffusion of impurities comprised within substrate to diffuse to the substrates outer surface, where it may contaminate for example a wafer in contact with the outer surface.

In some embodiments, the distance between the proximal section and the distal section may be at least about 200 μm, more specifically at least about 400 μm and in particular at least about 600 μm. A greater distance between the proximal section and the distal section relates to a greater section of the wall segment being homogenously coated, which improves the chemical resistance of the wall segment.

In some embodiments, the distance between the proximal section and the edge may be at least about 200 μm, more specifically at least about 400 μm and in particular at least about 600 μm.

In some embodiments, the distance between the proximal section and the edge may be between about 200 μm to about 2 cm, more specifically between about 400 μm to about 1 cm and in particular between about 600 μm to about 800 μm. The proximal section disposed further away from the edge signifies that the metal carbide coating was applied deeper into the recess, which in turn corresponds to a better chemical resistance deeper within the recess.

In some embodiments, the outer surface also may comprise the metal carbide coating. The substrate, for example graphite, may have a rough outer surface. The rough outer surface may damage objects, for example wafers, placed on the substrate's outer surface. A metal carbide coating may level and/or smoothen the outer surface and reduce the risk of damaging object placed on the substrate.

In some embodiments, the thickness of the metal carbide coating of the distal section may be between about 80% to about 200%, more specifically between about 90% to about 160% and in particular between about 95% to about 120% of the thickness of the metal carbide coating of the proximal section. The above mentioned ranges specify a metal carbide coating of high homogeneity, which may improve the overall chemical resistance of the substrate. The method according to the first aspect, may be even able to provide a metal carbide coating with a step coverage above 100%, as can be seen in FIGS. 2 and 4. Coatings with a step coverage above 100% may be referred to as superconformal coatings. As mentioned above, the processes involved in chemical vapor deposition are not fully understood. However, without wishing to be bound by theory, the method according to the first aspect may be able to provide a superconformal metal carbide coating, as chlorine which desorbs from the surface where the reactive species forms the metal carbide coating, may reabsorb on the way of diffusing out of the recess. Due to the readsorption the chlorine may again block the deposition of the metal carbide coating onto the substrate. During the method, the chlorine concentration may increase along the wall segment towards the edge, as the chlorine accumulates along the pathway towards the edge. Hence, the chlorine may, depending on also for example the temperature, block more reactive sites at the top of the recess compared to the bottom of the recess.

Again, without wishing to be bound by theory, the precursor may also breakdown into smaller fragments within main gas flow. These smaller fragments may comprise chlorine containing species, in particular HCl if chlorine reacts with hydrogen present in the main gas flow. The chlorine may preferentially react with the graphite substrate surface compared to other precursor fragments, reducing the growth rate of the metal carbide coating on the surface. As the chlorine may be depleted from main gas flow at the outer surface and parts of a recess disposed closer to the outer surface due to the surface reaction, lower parts of the recess may be exposed to lower chlorine concentrations. The precursor may also be depleted in lower parts of the recess compared to the outer surface or parts of the recess disposed closer to the outer surface. However, the depletion of the chlorine in the lower recess part may leave more reaction sites available for the precursor, thus leading to an equal or even increased rate of metal carbide coating formation at lower parts of a recess compared to the outer surface. In particular, the chlorine concentration may deplete more significantly compared to the precursor concentration further into the recess, leading to a shift in their ratio to one another, shifting the reaction equilibrium towards surface reactions with the precursor.

In some embodiments, the thickness of the metal carbide coating of the distal section may be between about 80% to about 200%, more specifically between about 90% to about 160% and in particular between about 95% to about 120% of the thickness of the metal carbide coating on the outer surface. The metal carbide coating provided by the method according to the first aspect may also provide a superconformal metal carbide coating when comparing the distal section to the outer surface.

In some embodiments, the wall segment may have a length of between about 200 μm to about 50 cm, more specifically between about 5 mm to about 40 cm and in particular between about 5 cm to about 30 cm.

### Orientation of Planes

In some embodiments, the wall segment and the outer surface may be disposed at an angle to one another, more specifically wherein the angle may be between about 45° to about 135°, in particular wherein the angle may be between about 70° to about 110° and even more particularly wherein the angle may be between about 85° to about 95°. Wall segments extending at an acute angle from the outer surface may be harder to coat, compared to flatter angles. The method according to the first aspect can be used to provide homogenous metal carbide coatings of a thickness of at least 100 μm on wall segments disposed at an acute angle from the outer surface.

In some embodiments, the wall segment and the outer surface may be disposed substantially orthogonally or orthogonally to one another.

In some embodiments, the wall segment may have an opposing wall segment, wherein the distance between the wall segment and the opposing wall segment may be between about 250 μm to about 25000 μm, more specifically between about 500 μm to about 10000 μm and in particular between about 1000 μm to about 7500 μm. For example, in a recess with a rectangular top view, the two opposing wall segments may be two opposed faces of the recess. In another example, in a circular recess the two opposing wall segments may be two circular arcs, wherein the two circular arcs are disposed opposed to one another. The distance between the wall segment and the opposing wall segment in a circular recess may then be the diameter of the circular recess.

In some embodiments, a ratio between a length of the wall segment and the distance between the wall segment and the opposing wall segment may be at least 1:1, more specifically at least 5:1, even more specifically at least 10:1 and in particular at least 20:1. The term “length of the wall segment” within this disclosure may refer to the distance between the edge and a lower edge disposed within the recess, wherein the lower edge is disposed further from the outer surface than the edge. For example, in a cubic recess, the length of the wall segment, may be the distance between the edge and the bottom of the recess. Additionally or alternatively, the term “length of the wall segment” within this disclosure may refer to the distance between the edge and the closest point on a line parallel to the outer surface which crosses the lower edge, wherein the lower edge is disposed further from the outer surface than the edge and no other edge is disposed within the recess closer to the outer surface and/or the edge. For example, in a recess comprising steps, the length of the wall segment may be longer than the distance to the first step. Instead the length of the wall segment may be the distance between the edge and the bottom of the recess, if the bottom of the recess were disposed on a line perpendicular to the outer surface which crosses the edge.

In some embodiments, the ratio between the length of the wall segment and the distance between the wall segment and the opposing wall segment may be between about 1:1 to about 100:1, more specifically between about 10:1 to about 75:1 and in particular between about 20:1 to about 50:1. Recesses of higher ratios may be harder to coat, as the recesses are narrow and/or deep.

### Edges

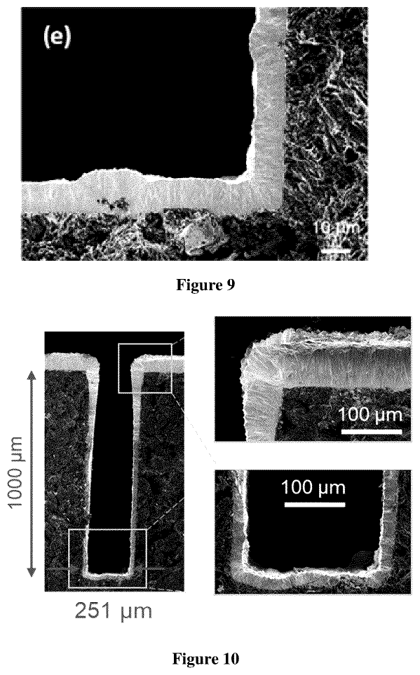

It was surprisingly found, that the method according to the first aspect, can provide a close contour metal carbide coating even at edges. FIG. 10 shows an SEM-image of a substrate edge coated by a conventional method and FIG. 9 shows an SEM-image of a substrate edge coated with the method according to the first aspect. As can be seen in FIG. 10 the edge coated by a conventional method results in a thicker metal carbide coating on both faces of the edge in an area proximal to the edge, ultimately forming a bulge on the edge. In comparison in FIG. 9, the edge coated with the method according to the first aspect results in an edge wherein the metal carbide coating closely follows the contour along the edge and the areas disposed proximal to the edge. The bulge generated in the conventional process may result in for example the object placed on the substrate not being in direct contact with the substrate. If the substrate is for example used a susceptor to heat the object, such as a wafer, the bulge may thus decrease the homogeneity and effectiveness of heat transfer, as it lifts the wafer away from the substrate's outer surface. Additionally, the bulge may constrict the diameter of the recess. For example, if the recess is or is part of a gas channel, the bulge may constrict the gas flow or introduce unwanted turbulences.

Removing the bulge may necessitate post-processing, which increases the cost of the final product. Further, post-processing may reduce the metal carbide coating thickness, damage the metal carbide coating or may not be possible.

In some embodiments, the metal carbide coating follows the contour of the underlying substrate, in particular wherein the metal carbide coating follows the contour of the underlying substrate at the edge.

In some embodiments, the variation of thickness of the metal carbide coating along the edge may be less than 60%, more specifically less than 50% and in particular less than 45%. Along a rectangular edge, the thickness of a perfectly contour close metal carbide coating, will vary in thickness by 41.4%, as the thickness of the metal carbide coating at the edge's vertex will have the thickness of the metal carbide coating in the areas proximal to the edge multiplied by the square root of 2.

In some embodiments, the outer surface may comprise a first portion adjacent to the edge and the wall segment may comprise a second portion adjacent to the edge, wherein the distance between the first portion and the edge and the distance between the second portion and the edge corresponds to 110% of the thickness of the metal carbide coating in the proximal section, and wherein the thickness of the metal carbide coating of the first portion may be between about 80% to about 120%, more specifically between about 90% to about 110% and in particular between about 95% to about 105% of the thickness of the metal carbide coating of the second portion.

As mentioned above, the thickness of the metal carbide coating may be determined perpendicular to the underlying surface. However, in the section directly adjacent to for example a sharp inner edge with 45°, the thickness of the metal carbide coating if measured perpendicular to the surface corresponds to the length of the wall segment. In a perfectly coated inner edge, the thickness of the c metal carbide coating in the second portion may not be measurable for a distance corresponding to the thickness of the metal carbide coating in the first portion.

In some embodiments, the thickness of the metal carbide coating of the first portion may be between about 80% to about 120%, more specifically between about 90% to about 110% and in particular between about 95% to about 105% of the thickness of the metal carbide coating in the proximal section.

In some embodiments, the thickness of the metal carbide coating of the second portion may be between about 80% to about 120%, more specifically between about 90% to about 110% and in particular between about 95% to about 105% of the thickness of the metal carbide coating in the proximal section.

In some embodiments, the edge may be an outer edge.

In some embodiments, the edge may be an inner edge.

### Substrate Material

In some embodiments, the substrate may comprise carbon, more specifically wherein the substrate may comprise at least about 90 wt.-% carbon and in particular wherein the substrate may comprise at least about 99 wt.-% carbon, relative to the total weight of the substrate.

In some embodiments, the substrate may comprise graphite, more specifically wherein the substrate may comprise at least about 90 wt.-% graphite and in particular wherein the substrate may comprise at least about 99 wt.-% graphite, relative to the total weight of the substrate. Graphite may exhibit high-temperature resistance. Further, graphite may be used as a susceptor to be heated my electromagnetic energy. However, graphite may be prone to chemical attack at high-temperatures. Coating graphite with a metal carbide coating and in particular a silicon carbide coating, may improve its chemical resistance and hence improve its usefulness at increased temperatures.

The term “graphite” is well known and attributed its common meaning in the art. More specifically, the term “graphite” may refer to a material comprising crystalline carbon in a hexagonal structure. Alternatively or additionally, the term “graphite” may refer to a material comprising at least about 60 at.-%, more specifically at least about 80 at.-% and in particular at least about 83 at.-% crystalline carbon in a hexagonal structure. Alternatively or additionally, the term “graphite” may refer to a material with a graphitization degree of at least about 69 at.-%, more specifically at least about 80 at.-% and in particular at least about 83 at.-%.

The graphitization degree of carbonaceous substrate may be measured by XRD. The crystalline carbon in the graphite forms a plurality of honeycomb lattice. XRD may be used to measure the interplane distance door between the plurality of lattices. Hence, the term “graphite” may additionally or alternatively refer to a carbonaceous material, wherein the carbonaceous material has a an interplane distance between about 0.3381 to about 0.3354, more specifically between about 0.3371 to about 0.3354 and in particular between about 0.3369 to about 0.3354. To perform the XRD measurement on a graphite substrate according to the present disclosure, the gradient and transition layer must be removed and only the underlying carbonaceous material shall be used for the measurement.

The interplane distance may also be used to calculate the graphitization degree by the following formula:

$$Graphitization Degree = \frac{0.3440 - {d}_{00 l}}{0.3440 - 0.3354}$$

The 0.3340 corresponds to the interplane distance of turbostratic graphite and the 0.3354 corresponds to the interplane distance in a perfect graphite crystal.

In some embodiments, the substrate may comprise silicon, more specifically wherein the substrate may comprise at least about 90 wt.-% silicon and in particular wherein the substrate may comprise at least about 99 wt.-% silicon, relative to the total weight of the substrate.

In some embodiments, the substrate may comprise isostatic graphite, more specifically wherein the substrate may comprise at least about 90 wt.-% isostatic graphite and in particular wherein the substrate may comprise at least about 99 wt.-% isostatic graphite, relative to the total weight of the substrate. Isostatic graphite may possess improved mechanical properties compared to other graphite types, such as extruded or vibromolded graphite. Further, the isostatic graphite may have pores of an average smaller pore diameter, which may allow the metal carbide coating to seal those pores, which may substantially improve the chemical resistance and/or reduce the risk of impurities from reaching objects placed on the substrate.

In some embodiments, the substrate may comprise CFRC (Carbon Fiber Reinforced Carbon), more specifically wherein the substrate may comprise at least about 90 wt.-% isostatic graphite and in particular wherein the substrate may comprise at least about 99 wt.-% CFRC, relative to the total weight of the substrate. CFRC may exhibit improved mechanical properties compared to other carbonaceous substrates.

In some embodiments, the substrate may be a cylinder, more specifically a cylinder with a diameter between about 5 cm to about 100 cm and in particular a cylinder with a diameter between about 15 cm to about 80 cm. The substrate being a cylinder may refer to the basic body of the cylinder being a cylinder, but the substrate comprising other features deviating from its basic body, e.g. recess disposed therein, edges, skirts along the outer circumference, etc.

In some embodiments, the cylinder may have thickness between about 1 mm to about 10 cm, more specifically between about 3 mm to about 5 cm and in particular between about 5 mm to about 3 cm.

The method according to the first aspect may be used to coat substrates of greater size compared to other chemical vapor deposition methods, in particular other chemical vapor deposition methods used to create homogenous metal carbide coatings.

In some embodiments, the outer surface may comprise at least one disc-shaped pocket, wherein the diameter of the pocket may be between about 45 mm to about 700 mm, more specifically between about 100 mm to about 475 mm and in particular between about 150 mm to about 300 mm and/or wherein the depth of the pocket may be between about 100 μm to about 2000 μm, more specifically between about 250 μm to about 1500 μm and in particular between about 500 μm to about 1000 μm. The disc-shaped pockets may be used to place for example wafers on the substrate and secure them in place, in particular if the substrate can be used as a susceptor, e.g. graphite.

### Coating Material

In some embodiments, the metal carbide coating may comprise at least about 90 wt.-% of a metal carbide, more specifically the metal carbide coating may comprise at least about 99 wt.-% of a metal carbide, relative to the total weight of the coating and in particular the metal carbide coating may consist of the metal carbide.

The term “metal carbide” coating herein may refer to any carbide comprising a metal, metalloid and/or transition metal. Metal carbide coatings according to any present disclosure may be, but not limited to, silicon carbide, titanium carbide, tantalum carbide or tungsten carbide.

In some embodiments, the metal carbide may comprise silicon carbide.

In some embodiments, the metal carbide coating may comprise a plurality of carbide crystals.

In some embodiments, the metal carbide coating may be characterized by a full-width-half-maximum of the (111) peak in an XRD between about 0.300° to about 1.000°, more specifically between about 0.350° to about 0.800° and in particular between about 0.400° to about 0.750°. The full-width half maximum of metal carbide coating produced by the method according to the first aspect may result in a greater full-width half maximum of the (111) peak in an XRD, compared to methods performed at higher temperatures. The higher full-width half maximum of the (111) peak may be correlated to a smaller crystal size in the metal carbide coating. Smaller crystals may form a smoother metal carbide coating compared to crystals of greater size, which in turn may reduce the roughness of the surface and improve the heat transfer to object placed on the metal carbide coating. The XRD measurement may be performed for example with a PANalytical X'Pert PRO Powder X-ray Diffractometer, by the company Malvern Panalytical, UK/Netherlands. The irradiation may be performed with a Cu K-alpha beam and Bragg-Brentano Geometry. The measurement mode may be set to theta-2theta and the measurement range to 20°-140° at a step size of 0.033°.

### Gas Channel

As mentioned above, the substrate may in some embodiments comprise one or more gas channels, for example to turn a wafer placed on the substrate. A gas channel is depicted in FIG. 8. These gas channels may comprise a first gas channel section (1000) extending from the outer surface, in particular perpendicular to the outer surface, into the bulk and then a second gas channel section (1200) extending parallel to the outer surface within the bulk. Between the first (1000) and the second (1200) gas channel section an edge (1100) may be disposed. Hence, a recess within the substrate may comprise a section which extends parallel to the outer surface within the bulk. It may be difficult to coat such recesses with a metal carbide coating of sufficient thickness.

In particular the section of the recess disposed within the bulk in parallel to the outer surface, may be shaded from the main gas flow and thus metal carbide coating this section relies on diffusion from the main gas flow into the recess section beneath the outer surface. In conventional methods the precursors may already be depleted when reaching the section of the recess disposed in parallel to the outer surface. The method according to the first aspect has been found to allow metal carbide coating these sections with a metal carbide coating of sufficient thickness as well. Without wishing to be bound by theory, it is believed that the reactive sites of the substrate may be blocked by chlorine, which hence prevents the reaction of precursor and/or reactive species with the substrate at the reactive sites. As a result, the precursor and/or reactive species can be carried further into the recess where it can react with reaction sites.

In some embodiments, the wall segment may comprise a first wall section and a second wall section, wherein the first and second wall section may be disposed at angle to one another.

In some embodiments, the second wall section extends orthogonally to the first wall section. As mentioned above, for example a gas channel may comprise a section disposed parallel to the outer surface, as depicted in FIG. 9. Hence, in some embodiments, the first wall section may extend orthogonally from the outer surface and the second section orthogonally from the first wall section, wherein the second wall section extends parallel to the outer surface. This may allow for example feeding a gas channel from an outer edge of the substrate.

In some embodiments, the first wall section may have a length between about 0.1 cm to about 3 cm, more specifically between about 0.5 cm to about 2 cm and in particular between about 1 cm to about 1.5 cm.

In some embodiments, the second wall section may have a length between about 1 cm to about 100 cm, more specifically between about 5 cm to about 75 cm and in particular between about 25 cm to about 50 cm.

In some embodiments, the recess may have a first and a second opening, wherein the first opening may be disposed within the outer surface and the second opening may be disposed on a second outer surface of the substrate. The second opening may for example be used to feed or remove a gas, such as air or an inert gas into/from the recess.

In some embodiments, a second edge may be disposed between the first and second wall segment, and wherein the first wall segment may comprise a third portion adjacent to the second edge and the second wall segment may comprise a fourth portion adjacent to the second edge, wherein the distance between the third portion and the second edge and the distance between the fourth portion and the edge corresponds to 110% of the thickness of the metal carbide coating in the proximal section, and wherein the thickness of the metal carbide coating of the first portion may be between about 80% to about 120%, more specifically between about 90% to about 110% and in particular between about 95% to about 105% of the thickness of the metal carbide coating of the second portion. As mentioned above, the method according to the first aspect may allow coating edges within the recess with a metal carbide coating of homogenous thickness. The second edge may be for example an edge with a gas channel, for example the edge disposed between a first bore perpendicular to the outer surface and a second bore extending parallel to the outer surface. Coating edges within gas channels with homogenous thickness may improve the flow behavior within the gas channel. In some embodiments, the second edge may be the lower edge.

In a third aspect, the present disclosure relates to a substrate comprising an outer surface and a recess disposed within the outer surface. The recess comprises a wall segment wherein there is an edge disposed between the outer surface and the wall segment. The outer surface and the wall segment comprise a metal carbide coating. Further, the wall segment comprises a proximal section, wherein the distance between the edge and the proximal section is 500 μm. The outer surface comprises a first portion adjacent to the edge and the wall segment comprises a second portion adjacent to the edge. The distance between the first portion and the edge and the distance between the second portion and the edge corresponds to 110% of the thickness of the metal carbide coating in the proximal section. Further, the thickness of the metal carbide coating of the first portion is between about 80% to about 120%, more specifically between about 90% to about 110% and in particular between about 95% to about 105% of the thickness of the metal carbide coating of the second portion. As mentioned above the method according to the first aspect may be used to provide metal carbide coatings with homogenous thickness along edges of the substrate. The technical advantages of metal carbide coatings with homogenous thickness along edges have been outlined above.

### Experimental Section

### Sample Preparation

The samples were prepared by coating isostatic graphite sold under the brand name Sigrafine 810 by the company SGL Carbon Group, Germany.

The cuboid samples had a length of 5 cm a width of 2.5 cm and a thickness of 0.2 cm before coating. The samples comprised a plurality of recesses with a depth of 1000 μm and a width of 300 μm running along the entire diameter of the sample. As reactor a lab-scale low-pressure CVD reactor was used. The reactor comprised a heatable graphite susceptor with a size of 20 cm×8 cm and thickness of 2 cm on which the samples were placed. The air was then evacuated from the reactor. The reactor was then flushed with carrier gas (H₂) and heated to the desired temperature. Then the process gas was introduced into the reactor to start the coating process. The composition of the process gas is outlined for each experiment below. The coating durations mentioned below relate to the duration the samples were exposed in the reactor to the process gas. The coating process was stopped by turning off the process gas flow and the reactor was flushed with carrier gas (H₂) and the reactor was allowed to cool. The reactor was again evacuated and refilled with inert gas. Subsequently, the reactor was opened and the samples were removed.

The samples were placed in a position in the oven where the oven exhibits a stable temperature profile and where the samples come into contact with the process gas flow, in particular a laminar process gas flow.

### First Experiment

In a second experiment the influence of temperature on the step coverage and average growth rate in a SiCl₄+Ethene-Process and an MTS-process was determined.

| Sample | Temper- | | | | | | | Dura- |
|---|---|---|---|---|---|---|---|---|
| No. | ature | | p(H₂) | | P(SiCl₄) | p(C₂H₄) | p(MTS) | tion |
| Example 1 | 950° | C. | 9.65 | mbar | 0.3 mbar | 0.15 mbar | | 30 min |
| Example 2 | 1000° | C. | 9.65 | mbar | 0.3 mbar | 0.15 mbar | | 30 min |
| Example 3 | 1100° | C. | 9.65 | mbar | 0.3 mbar | 0.15 mbar | | 30 min |
| Example 4 | 1200° | C. | 9.65 | mbar | 0.3 mbar | 0.15 mbar | | 30 min |
| Comparative | 950° | C. | 9.65 | mbar | | | 0.3 mbar | 30 min |
| Example 1 | | | | | | | | |
| Comparative | 1000° | C. | 9.7 | mbar | | | 0.3 mbar | 30 min |
| Example 2 | | | | | | | | |
| Comparative | 1100° | C. | 9.7 | mbar | | | 0.3 mbar | 30 min |
| Example 3 | | | | | | | | |
| Comparative | 1200° | C. | 9.7 | mbar | | | 0.3 mbar | 30 min |
| Example 4 | | | | | | | | |

The results are shown in FIG. 2 and FIG. 3. The step coverage was determined by measuring the metal carbide coating thickness at the bottom of the recess compared to the metal carbide coating at the top of the recess in a section disposed next to the edge.

FIG. 2 shows that the step coverage of the CVD-process using SiCl₄ was greater than the step coverage in the CVD-process using MTS. Further, the step coverage was at a maximum between about 950° C. to about 1100° C. and in particular at around 1000° C. Further, FIG. 3 shows that the average growth rate of the SiCl₄-process was significantly above the average growth rate of the MTS process in a temperature window between 950° C. to beyond 1100° C. To measure the average growth rate, the growth rate at 10 points disposed along a wall of a recess were measured. The growth rate was measured at the outer surface of the substrate 5 μm from the edge and at the bottom of the recess. The additional 8 points were disposed in equidistant intervals between the edge and the bottom. Additionally, FIG. 3 shows that average growth rate in SiCl₄ process declines beyond 1100° C., whereas the average growth rate in the MTS greatly increases beyond 1100° C.

### Second Experiment

In a second experiment the influence of partial pressure on the step coverage and average growth rate in a SiCl₄+Ethene-Process and an MTS-process was determined.

| Sample | Temper- | | | | | | | Dura- |
|---|---|---|---|---|---|---|---|---|
| No. | ature | p(H₂) | | P(SiCl₄) | p(C₂H₄) | | p(MTS) | tion |
| Example 5 | 950° C. | 9.85 | mbar | 0.1 mbar | 0.05 | mbar | | 30 min |
| Example 6 | 950° C. | 9.7 | mbar | 0.2 mbar | 0.1 | mbar | | 30 min |
| Example 7 | 950° C. | 9.55 | mbar | 0.3 mbar | 0.15 | mbar | | 30 min |
| Example 8 | 950° C. | 9.4 | mbar | 0.4 mbar | 0.2 | mbar | | 30 min |
| Comparative | 950° C. | 9.9 | mbar | | | | 0.1 mbar | 30 min |
| Example 5 | | | | | | | | |
| Comparative | 950° C. | 9.8 | mbar | | | | 0.2 mbar | 30 min |
| Example 6 | | | | | | | | |
| Comparative | 950° C. | 9.7 | mbar | | | | 0.3 mbar | 30 min |
| Example 7 | | | | | | | | |
| Comparative | 950° C. | 9.6 | mbar | | | | 0.4 mbar | 30 min |
| Example 8 | | | | | | | | |

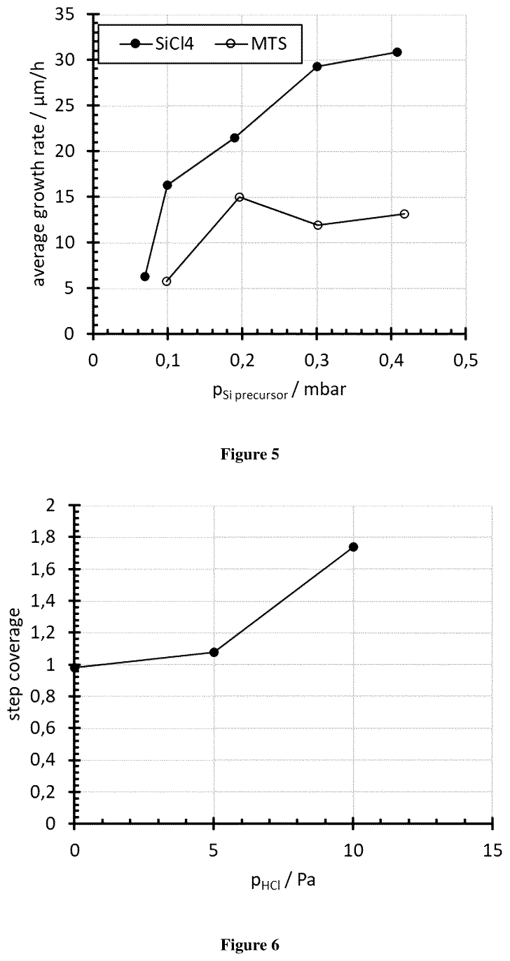

FIG. 4 and FIG. 5 show the results of the second experiment. With increasing partial pressure of the SiCl₄ the step coverage increases, whereas the step coverage with MTS decreases beyond a partial pressure of 0.2 mbar. Further, the average growth rate increases with increasing SiCl₄ partial pressure, though the rate of increase declines with increasing partial pressure. The MTS achieves a maximum at 0.2 mbar partial pressure and declines beyond that.

### Third Experiment

In a third experiment the influence of HCl on the step coverage and average growth rate in a SiCl₄+Ethene-Process was determined.

| | Tem- | | | | | |
|---|---|---|---|---|---|---|
| Sample | per- | | | | | Dura- |
| No. | ature | p(H₂) | P(SiCl₄) | p(C₂H₄) | p(HCl) | tion |
| Exam- | 950° C. | 9.65 mbar | 0.3 mbar | 0.15 mbar | 0 | 30 min |
| ple 9 | | | | | | |
| Exam- | 950° C. | 9.60 mbar | 0.3 mbar | 0.15 mbar | 5 | 30 min |
| ple 10 | | | | | | |
| Exam- | 950° C. | 9.55 mbar | 0.3 mbar | 0.15 mbar | 10 | 30 min |
| ple 11 | | | | | | |

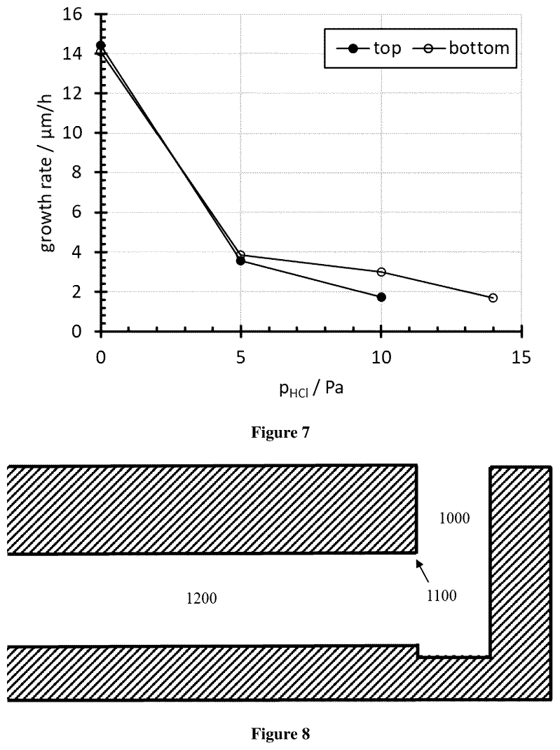

The results are shown in FIG. 6 and FIG. 7. The results show, that with increasing HCl partial pressure the step coverage may be increased, but the average growth is significantly reduced.

### Fourth Experiment

In a fourth experiment, different full-width half-maximum values of the SiC-(111) peak were measured at different process conditions.

The XRD measurement was be performed with a PANalytical X'Pert PRO Powder X-ray Diffractometer, by the company Malvern Panalytical, UK/Netherlands. The irradiation was performed with a Cu K-alpha beam and Bragg-Brentano Geometry. The measurement mode was set to theta-2theta and the measurement range to 20°-140° at a step size of 0.033°.

| Sample | Temper- | | | Ratio | Ratio | Dura- | | |
|---|---|---|---|---|---|---|---|---|
| No. | ature | | p(SiCl₄) | H₂/Si | Cl/Si | tion | | FWHM |
| Exam- | 950° | C. | 30 mbar | 32 | 4 | 30 | min | 0.659° |
| ple 12 | | | | | | | | |
| Exam- | 1000° | C. | 30 mbar | 32 | 4 | 30 | min | 0.449° |
| ple 13 | | | | | | | | |
| Exam- | 950° | C. | 20 mbar | 50 | 4 | 15 | min | 0.414° |
| ple 14 | | | | | | | | |
| Exam- | 950° | C. | 20 mbar | 50 | 4.25 | 15 | min | 0.606° |
| ple 15 | | | | | | | | |
| Exam- | 950° | C. | 20 mbar | 50 | 4.5 | 30 | min | 0.548° |
| ple 16 | | | | | | | | |
| Exam- | 950° | C. | 20 mbar | 50 | 4.5 | 180 | min | 0.718° |
| ple 17 | | | | | | | | |

As can be seen, all full-width half maxima are within a range between about between about 0.300 to about 1.000, more specifically between about 0.350 to about 0.800 and in particular between about 0.400 to about 0.750.

### ASPECTS

1. A substrate comprising:
   An outer surface and a recess disposed within the outer surface,
   wherein the recess comprises a wall segment comprising a metal carbide coating,
   wherein there is an edge disposed between the outer surface and the wall segment,
   wherein the wall segment comprises a proximal section and a distal section,
   wherein the proximal section is located closer to the edge compared to the distal section, and wherein the distance between the proximal section and the distal section in a direction perpendicular to the outer surface is at least 100 μm, and
   wherein the metal carbide coating in the distal section has at least 70% of the thickness of the metal carbide coating in the proximal section.

### Coating Dimensions

2. The substrate according to aspect 1, wherein the thickness of the metal carbide coating in the proximal section is between about 20 μm to about 300 μm, more specifically between about 50 μm to about 250 μm and in particular between about between about 80 μm to about 150 μm.
3. The substrate according to any preceding aspect, wherein the distance between the proximal section and the distal section is at least about 200 μm, more specifically at least about 400 μm and in particular at least about 600 μm.
4. The substrate according to any preceding aspect, wherein the distance between the proximal section and the distal section is between about 200 μm to about 2 cm, more specifically between about 400 μm to about 1 cm and in particular between about 600 μm to about 800 μm.
5. The substrate according to any preceding aspect, wherein the distance between the proximal section and the edge is at least about 200 μm, more specifically at least about 400 μm and in particular at least about 600 μm.
6. The substrate according to any preceding aspect, wherein the distance between the proximal section and the edge is between about 200 μm to about 2 cm, more specifically between about 400 μm to about 1 cm and in particular between about 600 μm to about 800 μm.
7. The substrate according to any preceding aspect, wherein the outer surface also comprises the metal carbide coating.
8. The substrate according to any preceding aspect, wherein the thickness of the metal carbide coating of the distal section is between about 80% to about 200%, more specifically between about 90% to about 160% and in particular between about 95% to about 120% of the thickness of the metal carbide coating of the proximal section.
9. The substrate according to any preceding aspect, wherein the thickness of the metal carbide coating of the distal section is between about 80% to about 200%, more specifically between about 90% to about 160% and in particular between about 95% to about 120% of the thickness of the metal carbide coating on the outer surface.
10. The substrate according to any preceding aspect, wherein the wall segment has a length of between about 200 μm to about 50 cm, more specifically between about 5 mm to about 40 cm and in particular between about 5 cm to about 30 cm.

### Orientation of Planes

11. The substrate according to any preceding aspect, wherein the wall segment and the outer surface are disposed at an angle to one another, more specifically wherein the angle is between about 45° to about 135°, in particular wherein the angle is between about 70° to about 110° and even more particularly wherein the angle is between about 85° to about 95°.
12. The substrate according to any preceding aspect, wherein the wall segment and the outer surface are disposed substantially orthogonally or orthogonally to one another.
13. The substrate according to any preceding aspect, wherein the wall segment has an opposing wall segment, wherein the distance between the wall segment and the opposing wall segment is between about 250 μm to about 25000 μm, more specifically between about 500 μm to about 10000 μm and in particular between about 1000 μm to about 7500 μm.
14. The substrate according to aspect 13, wherein a ratio between a length of the wall segment and the distance between the wall segment and the opposing wall segment is at least 1:1, more specifically at least 5:1, even more specifically at least 10:1 and in particular at least 20:1.
15. The substrate according to aspect 13 or 14, wherein the ratio between the length of the wall segment and the distance between the wall segment and the opposing wall segment is between about 1:1 to about 100:1, more specifically between about 10:1 to about 75:1 and in particular between about 20:1 to about 50:1.

### Edges

16. The substrate according to any preceding aspect, wherein the metal carbide coating follows the contour of the underlying substrate, in particular wherein the metal carbide coating follows the contour of the underlying substrate at the edge.
17. The substrate according to any preceding aspect, wherein the variation of thickness of the metal carbide coating along the edge is less than 60%, more specifically less than 50% and in particular less than 45%.
18. The substrate according to any preceding aspect, wherein the outer surface comprises a first portion adjacent to the edge and the wall segment comprises a second portion adjacent to the edge,
   wherein the distance between the first portion and the edge and the distance between the second portion and the edge corresponds to 110% of the thickness of the metal carbide coating in the proximal section,
   and wherein the thickness of the metal carbide coating of the first portion is between about 80% to about 120%, more specifically between about 90% to about 110% and in particular between about 95% to about 105% of the thickness of the metal carbide coating of the second portion.
19. The substrate according to aspect 18, wherein the thickness of the metal carbide coating of the first portion is between about 80% to about 120%, more specifically between about 90% to about 110% and in particular between about 95% to about 105% of the thickness of the metal carbide coating in the proximal section.
20. The substrate according to aspect 18 or 19, wherein the thickness of the metal carbide coating of the second portion is between about 80% to about 120%, more specifically between about 90% to about 110% and in particular between about 95% to about 105% of the thickness of the metal carbide coating in the proximal section.
21. The substrate according to any preceding aspect, wherein the edge is an outer edge.
22. The substrate according to any one of aspects 1 to 20, wherein the edge is an inner edge.

### Substrate Material

23. The substrate according to any preceding aspect, wherein the substrate comprises carbon, more specifically wherein the substrate comprises at least about 90 wt.-% carbon and in particular wherein the substrate comprises at least about 99 wt.-% carbon, relative to the total weight of the substrate.
24. The substrate according to any preceding aspect, wherein the substrate comprises graphite, more specifically wherein the substrate comprises at least about 90 wt.-% graphite and in particular wherein the substrate comprises at least about 99 wt.-% graphite, relative to the total weight of the substrate.
25. The substrate according to any preceding aspect, wherein the substrate comprises silicon, more specifically wherein the substrate comprises at least about 90 wt.-% silicon and in particular wherein the substrate comprises at least about 99 wt.-% silicon, relative to the total weight of the substrate.
26. The substrate according to any preceding aspect, wherein the substrate comprises isostatic graphite, more specifically wherein the substrate comprises at least about 90 wt.-% isostatic graphite and in particular wherein the substrate comprises at least about 99 wt.-% isostatic graphite, relative to the total weight of the substrate.
27. The substrate according to any preceding aspect, wherein the substrate comprises CFRC, more specifically wherein the substrate comprises at least about 90 wt.-% isostatic graphite and in particular wherein the substrate comprises at least about 99 wt.-% CFRC, relative to the total weight of the substrate.
28. The substrate according to any preceding aspect, wherein the substrate is a cylinder, more specifically a cylinder with a diameter between about 5 cm to about 100 cm and in particular a cylinder with a diameter between about 15 cm to about 80 cm.
29. The substrate according to aspect 28, wherein the cylinder has thickness between about 1 mm to about 10 cm, more specifically between about 3 mm to about 5 cm and in particular between about 5 mm to about 3 cm.
30. The substrate according to any preceding aspect, wherein the outer surface comprises at least one disc-shaped pocket, wherein the diameter of the recess is between about 20 mm to about 700 mm, more specifically between about 45 mm to about 475 mm and in particular between about 100 mm to about 300 mm and/or wherein the depth of the recess is between about 150 μm to about 2000 μm, more specifically between about 250 μm to about 1500 μm and in particular between about 500 μm to about 1000 μm.
   Metal carbide coating Material
31. The substrate according to any preceding aspect, wherein the metal carbide coating comprises at least about 90 wt.-% of a metal carbide, more specifically the metal carbide coating may comprise at least about 99 wt.-% of a metal carbide, relative to the total weight of the coating and in particular the metal carbide coating may consist of the metal carbide.
32. The substrate according to any preceding aspect, wherein the metal carbide comprises silicon carbide.
33. The substrate according to any preceding aspect, wherein the metal carbide coating comprises a plurality of carbide crystals.
34. The substrate according to any preceding aspect, wherein the metal carbide coating is characterized by a full-width-half-maximum of the (111) between about 0.300 to about 1.000, more specifically between about 0.350 to about 0.800 and in particular between about 0.400 to about 0.750, measured by XRD.

### Gas Channel

35. The substrate according to any preceding aspect, wherein the wall segment comprises a first wall section and a second wall section, wherein the first and second wall section are disposed at angle to one another.
36. The substrate according to aspect 35, wherein the second wall section extends orthogonally to the first wall section.
37. The substrate according to aspect 35 or 36, wherein the first wall section has a length between about 0.1 cm to about 3 cm, more specifically between about 0.5 cm to about 2 cm and in particular between about 1 cm to about 1.5 cm.
38. The substrate according to any one of aspect 35 to 37, wherein the second wall section has a length between about 1 cm to about 100 cm, more specifically between about 5 cm to about 75 cm and in particular between about 25 cm to about 50 cm.
39. The substrate according to any preceding aspect, wherein the recess has a first and a second opening, wherein the first opening is disposed within the outer surface and the second opening is disposed on a second outer surface of the substrate.
40. The substrate according to any one of aspects 35 to 39, wherein a second edge is disposed between the first and second wall section,
   and wherein the first wall section comprises a third portion adjacent to the second edge and the second wall section comprises a fourth portion adjacent to the second edge, wherein the distance between the third portion and the second edge and the distance between the fourth portion and the edge corresponds to 110% of the thickness of the metal carbide coating in the proximal section,
   and wherein the thickness of the metal carbide coating of the first portion is between about 80% to about 120%, more specifically between about 90% to about 110% and in particular between about 95% to about 105% of the thickness of the metal carbide coating of the second portion.

### Process

41. A method for coating a substrate with a metal or transition metal carbide by thermal chemical vapor deposition, wherein the method comprises:
   placing a substrate in a reaction chamber, and
   supplying the reaction chamber with SiCl4, ethene and a carrier gas,
   and wherein a process temperature in the reaction chamber is between about 900° C. to about 1050° C.
42. The method according to aspect 41, wherein the process temperature is between about 925° C. to about 1025° C., more specifically between about 950° C. to about 1000° C.
43. The method according to aspect 41 or 42, wherein the method takes place for a duration between about 20 min to about 600 min, more specifically between about 40 min to about 400 min and in particular between about 60 min to about 240 min.
44. The method according to any one of aspects 41 to 43, wherein the total pressure in the reaction chamber is between about 1 mbar to about 1085 mbar, more specifically between about 5 mbar to about 100 mbar and in particular between about 7 mbar to about 15 mbar.
45. The method according to any one of aspects 41 to 44, wherein the SiCl₄ and the ethene are supplied as a precursor mixture, wherein the atomic ratio between silicon and carbon in the precursor mixture is between about 0.7 to about 1.3, more specifically between about 0.8 to about 1.2, and in particular between about 0.9 to about 1.1.
46. The method according to any one of aspects 41 to 44, wherein the method may comprise a first and second step, wherein the first step comprises supplying the SiCl₄ to the reaction chamber and the second step comprises supplying the ethene to the reaction chamber, in particular wherein the first step and the second step alternate.
47. The method according to aspect 46, wherein the method may comprise a purge step, wherein the purge step takes place between the first and the second step and/or between the second step and first step, wherein the purge step comprises supplying the reaction with only carrier gas.
48. The method according to aspect 46 or 47, wherein the duration of the first and/or second step may be between about 1 s to about 5 s, more specifically between about 2.5 s to about 3.5 s and/or the duration of the purge step may be between about 0.5 s to about 3 s, more specifically between about 0.8 s to about 1.2 s.
49. The method according to any preceding aspect, wherein the carrier gas additionally comprises HCl or Cl₂, and in particular HCl.
50. The method according to aspect 45 or 49, wherein the atomic ratio between chlorine and silicon is between about 3.5:1 to about 5:1, more specifically between about 3.8:1 to about 4.7:1 and in particular between about 4:1 to about 4.5:1 in the precursor mixture.
51. The method according to any preceding aspect, wherein the carrier gas comprises H₂, more specifically wherein the molar ratio between H₂ and silicon is between about 10:1 to about 100:1, even more specifically between about 20:1 to about 70:1 and in particular between about 32:1 to about 50:1 in an aggregate of the carrier gas and the precursor mixture.
52. The method according to any preceding aspect, wherein the carrier gas additionally comprises an inert gas, more specifically N₂ and/or Ar and in particular N₂.

1-15. (canceled)

16. A substrate comprising:
An outer surface and a recess disposed within the outer surface,
wherein the recess comprises a wall segment comprising a metal carbide coating,
wherein there is an edge disposed between the outer surface and the wall segment,
wherein the wall segment comprises a proximal section and a distal section,
wherein the proximal section is located closer to the edge compared to the distal section,
and wherein the distance between the proximal section and the distal section in a direction perpendicular to the outer surface is at least 100 μm, and
wherein the metal carbide coating in the distal section has at least 70% of the thickness of the metal carbide coating in the proximal section.

17. The substrate according to claim 16, wherein the thickness of the metal carbide coating in the proximal section is between about 20 μm to about 300 μm, more specifically between about 50 μm to about 250 μm and in particular between about between about 80 μm to about 150 μm.

18. The substrate according to claim 16, wherein the distance between the proximal section and the distal section is at least about 200 μm, more specifically at least about 400 μm and in particular at least about 600 μm.

19. The substrate according to claim 16, wherein the distance between the proximal section and the edge is at least about 200 μm, more specifically at least about 400 μm and in particular at least about 600 μm.

20. The substrate according to claim 16, wherein the outer surface also comprises the metal carbide coating.

21. The substrate according to claim 16, wherein the thickness of the metal carbide coating of the distal section is between about 80% to about 200%, more specifically between about 90% to about 160% and in particular between about 95% to about 120% of the thickness of the metal carbide coating of the proximal section.

22. The substrate according to claim 16, wherein the thickness of the metal carbide coating of the distal section is between about 80% to about 200%, more specifically between about 90% to about 160% and in particular between about 95% to about 120% of the thickness of the metal carbide coating on the outer surface.

23. The substrate according to claim 16, wherein the wall segment has an opposing wall segment, wherein the distance between the wall segment and the opposing wall segment is between about 250 μm to about 25000 μm, more specifically between about 500 μm to about 10000 μm and in particular between about 1000 μm to about 7500 μm.

24. The substrate according to claim 16, wherein the outer surface comprises a first portion adjacent to the edge and the wall segment comprises a second portion adjacent to the edge, wherein the distance between the first portion and the edge and the distance between the second portion and the edge corresponds to 110% of the thickness of the metal carbide coating in the proximal section,
and wherein the thickness of the metal carbide coating of the first portion is between about 80% to about 120%, more specifically between about 90% to about 110% and in particular between about 95% to about 105% of the thickness of the metal carbide coating of the second portion.

25. The substrate according to claim 16, wherein the substrate comprises carbon, in particular graphite, more specifically wherein the substrate comprises at least about 90 wt.-% carbon and in particular wherein the substrate comprises at least about 99 wt.-% carbon, relative to the total weight of the substrate; or
wherein the substrate comprises silicon, more specifically wherein the substrate comprises at least about 90 wt.-% silicon and in particular wherein the substrate comprises at least about 99 wt.-% silicon, relative to the total weight of the substrate.

26. The substrate according to claim 16, wherein the metal carbide comprises silicon carbide.

27. The substrate according to claim 16, wherein the metal carbide coating is characterized by a full-width-half-maximum of the (111) between about 0.300 to about 1.000, more specifically between about 0.350 to about 0.800 and in particular between about 0.400 to about 0.750, measured by XRD.

28. The substrate according to claim 16, wherein a second edge is disposed between the first and second wall section,
and wherein the first wall section comprises a third portion adjacent to the second edge and the second wall section comprises a fourth portion adjacent to the second edge, wherein the distance between the third portion and the second edge and the distance between the fourth portion and the edge corresponds to 110% of the thickness of the metal carbide coating in the proximal section,
and wherein the thickness of the metal carbide coating of the first portion is between about 80% to about 120%, more specifically between about 90% to about 110% and in particular between about 95% to about 105% of the thickness of the metal carbide coating of the second portion.

29. A method for coating a substrate with a metal or transition metal carbide by thermal chemical vapor deposition, wherein the method comprises:
placing a substrate in a reaction chamber, and
supplying the reaction chamber with SiCl₄, ethene and a carrier gas,
and wherein a process temperature in the reaction chamber is between about 900° C. to about 1050° C.

30. The method according to claim 29, wherein the carrier gas additionally comprises HCl or Cl₂, and in particular HCl.
